(19) United States
(12) Patent Application Publication
(10) Pub. No.: US 2010/0259335 A1
(43) Pub. Date: Oct. 14, 2010

(54) RESISTORLESS FEEDBACK BIASING FOR ULTRA LOW POWER CRYSTAL OSCILLATOR

(75) Inventor: Woowai Martin, Phoenix, AZ (US)

Correspondence Address: King & Spalding LLP, 401 Congress Avenue, Suite 3200, Austin, TX, 78701, US

(73) Assignee: Microchip Technology Incorporated

(21) Appl. No.: 12/719,235

(22) Filed: Mar. 8, 2010

Related U.S. Application Data
(60) Provisional application No. 61/168,689, filed on Apr. 13, 2009.

(51) Int. Cl. H03B 5/36

(52) U.S. Cl. 331/116 FE

(57) ABSTRACT

An operational transconductance amplifier (OTA) is used as the DC bias feedback of a crystal oscillator to minimize temperature, voltage and process corner variations thereof, and thereby improve the reliability of crystal oscillator operation at ultra low power levels.

### RELATED PATENT APPLICATION

This application claims priority to commonly owned U.S. Provisional Patent Applications Ser. No. 61/168,689; filed Apr. 13, 2009; entitled “Resistorless Feedback Biasing for Ultra Low Power Crystal Oscillator,” by Woowai Martin, and is hereby incorporated by reference herein for all purposes.

### TECHNICAL FIELD

The present disclosure relates to integrated circuit devices, and, more particularly, to integrated circuit devices having resistorless feedback biasing for an ultra low power crystal oscillator.

### BACKGROUND

FIG. 1 illustrates a schematic diagram of a prior technology feedback resistor bias circuit configuration for a crystal oscillator. A conventional on-chip transistor-style feedback resistor 106 has very large variation over temperature, supply voltage and process corners. Therefore, there is a very large variation (over temperature, supply voltage and process corners) when used as an on-chip transistor-style feedback resistor 106 for crystal oscillator circuits. This variation causes oscillator start-up to be unreliable because of a shift in DC bias operating point and current leakage, Iₗₑₐₖ, through the resistor 106 that diverts current I_{bias}−Iₗₑₐₖ=I_{osc} from the oscillator transistor 104.

### SUMMARY

Therefore, what is needed is a way of eliminating the very large variation (over temperature, supply voltage and process corners) of on-chip transistor-style feedback resistor used in crystal oscillators. This variation causes oscillator start-up unreliable. In addition, it is desired to allow very low power operation where the oscillator can be biased at 100 nA and below 1.0 volt operation.

According to the teachings of this disclosure, an operational transconductance amplifier (OTA) connected as the crystal oscillator feedback has only an input offset voltage variation which is easily controlled to less than 10-20 mV over all temperature, voltage and process corners, resulting in a large margin for low voltage oscillator operation. In addition, the OTA bias scheme is transparent to the oscillator design equations, thus simplifying oscillator analysis mathematically. Use of this low power OTA bias scheme, according to the teachings of this disclosure, overcomes on-chip feedback resistor leakage and resistance value variation, thereby allowing more reliable crystal oscillator operation at ultra low power levels.

According to a specific example embodiment of this disclosure, an ultra-low power crystal oscillator comprises: an oscillator driver transistor having a source, gate and drain; a low operating current operational transconductance amplifier (OTA) having positive and negative inputs and an output, wherein the OTA is connected in a unity gain buffer configuration; and a bias current generator connected to a supply voltage, the bias current generator setting a direct current (DC) voltage at the drain of the oscillator driver transistor; wherein the positive input of the OTA is connected to the drain of the oscillator driver transistor and the bias current generator, and the negative input and output of the OTA are connected to the gate of the oscillator driver transistor, whereby the gate and drain DC bias voltages of the oscillator driver transistor are substantially the same; and the voltages on the negative and positive inputs of the OTA are substantially the same while the oscillator driver transistor AC operation remains undisturbed.

According to another specific example embodiment of this disclosure, an ultra-low power crystal oscillator comprises: a start-up circuit, a bias current generator coupled to the start-up circuit; a low operating current operational transconductance amplifier (OTA) feedback circuit coupled to the bias current generator; a crystal oscillator transistor coupled to the OTA feedback circuit; and an oscillator buffer amplifier coupled to the crystal oscillator transistor.

### BRIEF DESCRIPTION OF THE DRAWINGS

A more complete understanding of the present disclosure thereof may be acquired by referring to the following description taken in conjunction with the accompanying drawings wherein:

FIG. 1 illustrates a schematic diagram of a prior technology feedback resistor bias circuit configuration for a crystal oscillator;

FIG. 2 illustrates a schematic diagram of an operational transconductance amplifier (OTA) bias circuit configuration for an ultra low power crystal oscillator, according to a specific example embodiment of this disclosure;

FIG. 3 illustrates a schematic block diagram of an OTA feedback biased ultra low power crystal oscillator, according to a specific example embodiment of this disclosure; and

FIG. 4 illustrates a schematic diagram of an OTA feedback bias circuit shown in FIG. 3, according to the teachings of this disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawing, the details of specific example embodiments are schematically illustrated. Like elements in the drawings will be represented by like numbers, and similar elements will be represented by like numbers with a different lower case letter suffix.

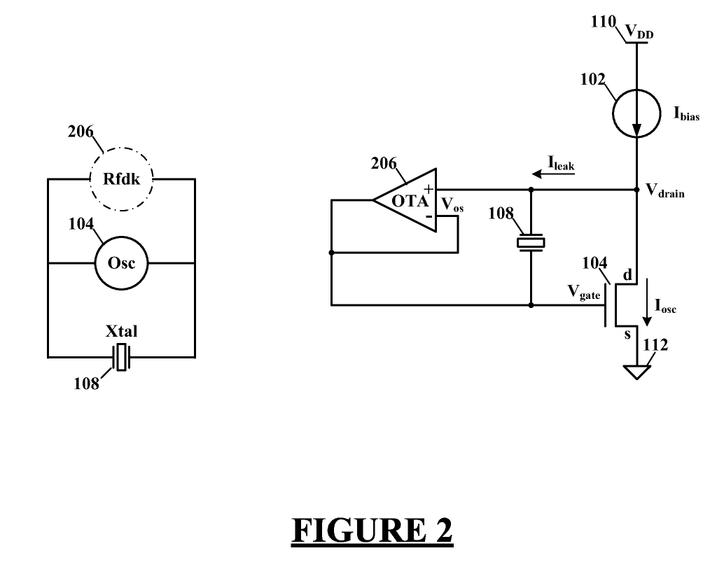

Referring to FIG. 2, depicted is a schematic diagram of an operational transconductance amplifier (OTA) bias circuit configuration for an ultra low power crystal oscillator, according to a specific example embodiment of this disclosure. A very weak (very low current) OTA 206 is connected in a unity gain buffer configuration. Its positive input is connected to the drain of the oscillator driver and its output and negative input are connected to the gate of the oscillator driver transistor 104. The goal is to set the oscillator DC bias voltages of the gate (V_{gate}) and drain (V_{drain}) as close to each other as possible. The weak OTA 206 operates to drive its negative input voltage equal to its positive input voltage at the same time keeping the oscillator AC operation undisturbed. A constant current bias generator 102 sets the DC voltage at the drain of the oscillator driver transistor 104. The OTA 206 will mirror this voltage to the gate of the oscillator driver transistor 104, therefore the DC bias voltages of the gate and drain will always be substantially equal (minus a very small input offset voltage of the OTA 206), e.g., Vgate=Vdrain−Vos, where Vos is the input offset voltage of the OTA 206.

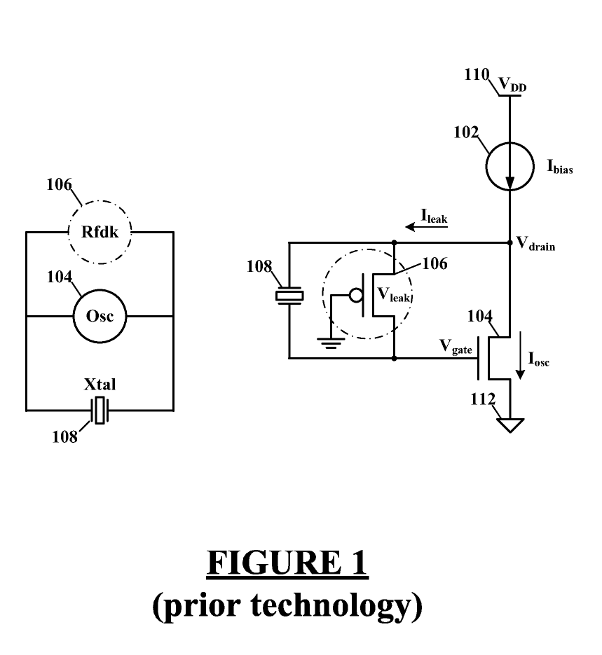

Over process and temperature the input offset voltage of the OTA 206 is much smaller than the leakage of a transistor-style feedback resistor (FIG. 1), making this a very reliable solution to the leakage and variation problems encountered in the transistor-style feedback network (shown in FIG. 1). This bias scheme is process and frequency independent. With this bias scheme, crystal oscillators can be biased to easily operate using a power source of under 1 volt. This oscillator, according to the teachings of this disclosure, may reliably operate down to 0.8 volt and may even work down to lower voltages. The oscillator driver transistor may be field effect transistor (FET), e.g., junction FET, insulated gate (IG) FET, metal oxide semiconductor (MOS) FET, etc.

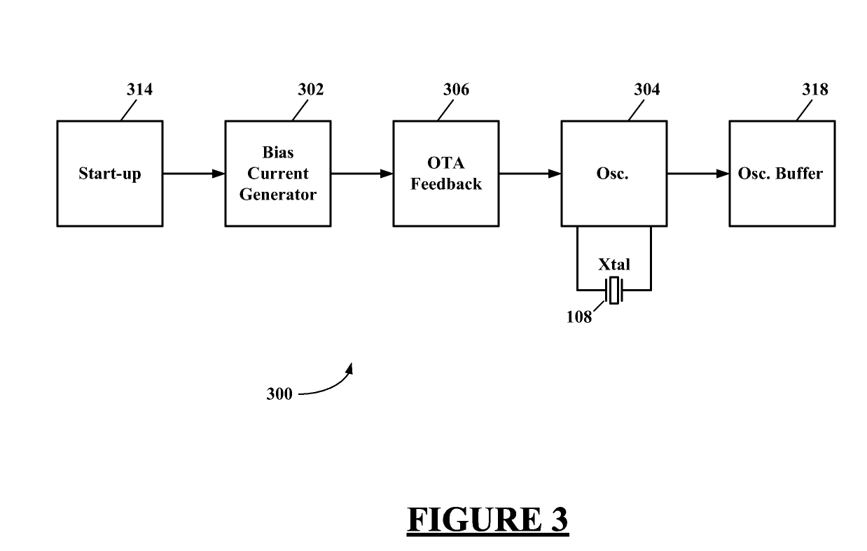

Referring to FIG. 3, depicted is a schematic block diagram of an OTA feedback biased ultra low power crystal oscillator, according to a specific example embodiment of this disclosure. The crystal oscillator, generally represented by the numeral 300, comprises a start-up circuit 314, a bias current generator 302, an OTA feedback circuit 306, an oscillator 304 and an oscillator buffer 318. The OTA feedback bias circuit 306 mirrors a current value from the bias current generator 302 to the oscillator 304, and may be configured as shown in FIG. 2. The crystal 108 determines the oscillation frequency of the crystal oscillator 300.

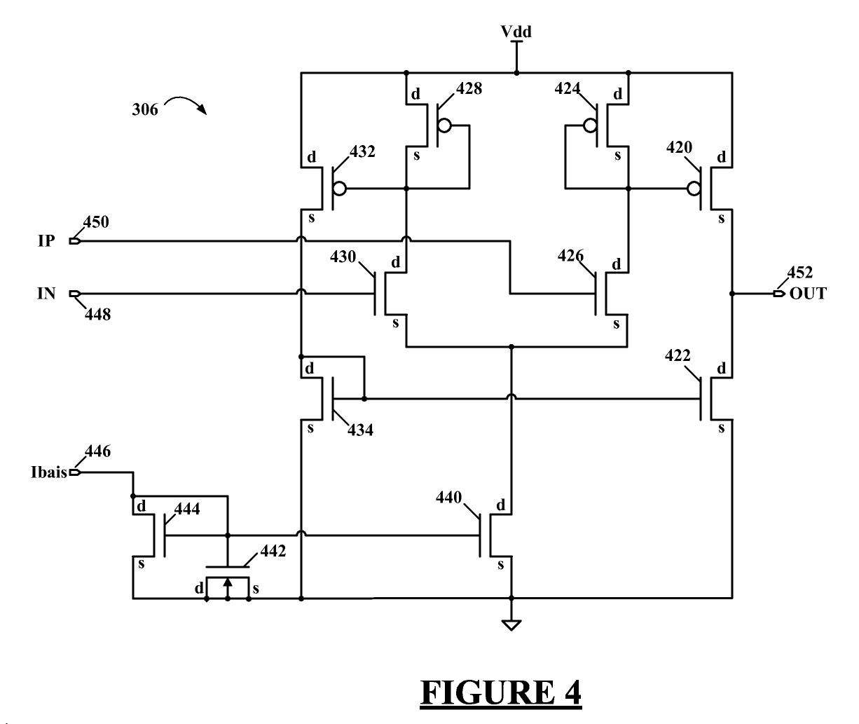

Referring to FIG. 4, depicted is a schematic diagram of the OTA feedback bias circuit shown in FIG. 3, according to the teachings of this disclosure. The OTA feedback bias circuit 306 has an output 452 and has differential inputs 450 (+) and 448 (−). The output 452 and the negative input 448 are connected to the gate of the oscillator transistor 104 (see FIG. 2), The positive input 450 is connected to the drain of the oscillator transistor 104 (see FIG. 2). The bias input 446 is connected to the bias current generator 302 (FIG. 3), and mirrors the current value therefrom to the oscillator transistor 104 (see FIG. 2).

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. An ultra-low power crystal oscillator, comprising:
an oscillator driver transistor having a source, gate and drain;
a low operating current operational transconductance amplifier (OTA) having positive and negative inputs and an output, wherein the OTA is connected in a unity gain buffer configuration as an oscillator feedback bias element; and
a bias current generator connected to a supply voltage, the bias current generator setting a direct current (DC) voltage at the drain of the oscillator driver transistor;
wherein the positive input of the OTA is connected to the drain of the oscillator driver transistor and the bias current generator, and the negative input and output of the OTA are connected to the gate of the oscillator driver transistor, whereby
the gate and drain DC bias voltages of the oscillator driver transistor are substantially the same; and
the voltages on the negative and positive inputs of the OTA are substantially the same while the oscillator driver transistor AC operation remains undisturbed.

2. The ultra-low power crystal oscillator according to claim 1, wherein the oscillator driver transistor is a field effect transistor (FET).

3. The ultra-low power crystal oscillator according to claim 1, wherein the oscillator driver transistor is a junction field effect transistor (JFET).

4. The ultra-low power crystal oscillator according to claim 1, wherein the oscillator driver transistor is an insulated gate (IG) field effect transistor (FET).

5. The ultra-low power crystal oscillator according to claim 1, wherein the oscillator driver transistor is a metal oxide semiconductor field effect transistor (MOSFET).

6. The ultra-low power crystal oscillator according to claim 1, wherein the bias current generator is a constant current source.

7. An ultra-low power crystal oscillator, comprising:
a start-up circuit,
a bias current generator coupled to the start-up circuit;
a low operating current operational transconductance amplifier (OTA) feedback circuit coupled to the bias current generator;
a crystal oscillator transistor coupled to the OTA feedback circuit; and
an oscillator buffer amplifier coupled to the crystal oscillator transistor.

8. The ultra-low power crystal oscillator according to claim 7, wherein the bias current generator is a a constant current source coupled to a supply voltage.

9. The ultra-low power crystal oscillator according to claim 7, wherein the (OTA) feedback circuit is a low operating current operational transconductance amplifier (OTA) having positive and negative inputs and an output, wherein the OTA is connected in a unity gain buffer configuration.

10. The ultra-low power crystal oscillator according to claim 7, wherein the crystal oscillator transistor is a field effect transistor (FET).

11. The ultra-low power crystal oscillator according to claim 7, wherein the oscillator transistor is a junction field effect transistor (JFET).

12. The ultra-low power crystal oscillator according to claim 7, wherein the oscillator transistor is an insulated gate (IG) field effect transistor (FET).

13. The ultra-low power crystal oscillator according to claim 7, wherein the oscillator transistor is a metal oxide semiconductor field effect transistor (MOSFET).
